(19) United States
(12) Patent Application Publication
(10) Pub. No.: US 2012/0267782 A1
(43) Pub. Date: Oct. 25, 2012

(54) PACKAGE-ON-PACKAGE SEMICONDUCTOR DEVICE

(76) Inventor: Yung-Hsiang CHEN, Kaohsiung (TW)

(21) Appl. No.: 13/093,436

(22) Filed: Apr. 25, 2011

(51) Int. Cl. H01L 23/498

(52) U.S. Cl. 257/738; 257/E23.069

(57) ABSTRACT

Disclosed is a package-on-package semiconductor device comprising a bottom package, a top package thereon and a ACA (Anisotropic Conductive Adhesive) layer. A plurality of ball pads are disposed on the peripheries of an upper surface of the substrate of the bottom package. A plurality of solder balls are disposed at the peripheries of the lower surface of the substrate of the top package. The ACA layer having a central opening is interposed between the bottom package and the top package where the ACA layer contains a plurality of conductive particles. Therein, the size of the central opening and the thickness of the ACA layer are selected such that the anisotropic conductive adhesive layer adheres the peripheries of the upper surface of the bottom package to the peripheries of the lower surface of the top package and the solder balls are encapsulated inside the anisotropic conductive adhesive layer. The solder balls encapsulate some of the conductive particles to mechanically joint and electrically connect to the ball pads. Thereby, the bonding strength of the solder balls can be improved and the warpage of the substrate of the bottom package is effectively reduced to avoid failure of electrical connections between both packages caused by the breaking of soldering joints.

### FIELD OF THE INVENTION

The present invention relates to a semiconductor device, and more specifically to a package-on-package semiconductor device.

### BACKGROUND OF THE INVENTION

Among the modern semiconductor packaging technology, a packaging product formed by stacking two semiconductor packages is developed to meet the requirements of multiple functions with high power within a smaller footprint, i.e., stacked package-on-package (POP) or 3D packages. POP is formed by vertically stacking two or more individual packages together through SMT where the packages have gone through final test (FT) to ensure good packages to form high-density packages with reduced SMT footprint and to avoid the risk of yield loss due to IC fabrication with different functions on a single IC and in a single package. Therefore, POP is an emerging stacked package with mature packaging technology to provide low-cost system-in-package (SIP) solutions, especially suitable for the integration of various complicated logic components with memory.

FIG. 1 and FIG. 2 are cross-sectional views of a conventional POP semiconductor device before and after assembly. The POP semiconductor device 100 includes a bottom package 110 and a top package 120 stacked on top where both packages are bonded together through a plurality of solder balls 123 of the top package 120 by surface mount technology (SMT). A first chip 112 is disposed on the first upper surface 111A of the first substrate 111 of the bottom package 110 with a plurality of ball pads 114 exposed at the peripheries of the first upper surface 111A for jointing the solder balls 123. A first encapsulant 115 is formed on the partial upper surface 111A of the first substrate 111 to encapsulate the first chip 112. A plurality of external terminals 113 are disposed on the lower surface 111B of the first substrate 111 for external electrical connections to a printed circuit board 10. A plurality of second chips 122 are disposed on the upper surface 121A of the second substrate 121 of the top package 120 where a second encapsulant 125 is formed on the upper surface 121A of the second substrate 121 to encapsulate the second chips 122. The solder balls 123 are disposed on the lower surface 121B of the second substrate 121. The solder balls 123 are aligned to and jointed to the ball pads 114 underneath to vertically stacked and electrically connect the top package 120 to the bottom package 110. With an appropriate reflowing process, the top package 120 is SMT bonded to the ball pads 114 of the bottom package 110 through the solder balls 123. The bottom package 110 are configured for SMT bonding to a printed circuit board 10 by the external terminals 113.

However, temperature of POP semiconductor device 100 rises during thermal cycling test or actual operation, thermal stresses would easily induce in the POP semiconductor device 100 due to the differences of coefficient of thermal expansion (CTE) in different materials in the POP semiconductor device 100, especially easily inducing warpage to the first substrate 111 caused poor joints such as missing solder or cold soldering 113A or breaking of solder balls 123A as shown in FIG. 2 leading to poor reliability of the POP semiconductor device 100.

### SUMMARY OF THE INVENTION

The main purpose of the present invention is to provide a POP semiconductor device to enhance the joints of embedded solder balls and to effectively reduce substrate warpage of the bottom package to resolve failure of electrical connection due to the breaking of soldering points between the top package and the bottom package.

According to the present invention, a POP semiconductor device is revealed, comprising a bottom package, a top package, and an anisotropic conductive adhesive (ACA) layer. The bottom package includes a first substrate, at least a first chip disposed on the first substrate, a plurality of external terminals disposed on a first lower surface of the first substrate, and a plurality of ball pads disposed at the peripheries of the first upper surface of the first substrate. The top package is mounted on the bottom package. The top package includes a second substrate, one or more second chips are disposed on the second substrate, and a plurality of solder balls disposed at the peripheries of the second lower surface of the second substrate. The ACA layer having a central opening is interposed between the bottom package and the top package where the ACA layer contains a plurality of conductive particles. The size of the central opening and the thickness of the anisotropic conductive adhesive layer are selected such that the anisotropic conductive adhesive layer adheres the peripheries of the first upper surface of the first substrate to the peripheries of the second lower surface of the second substrate with the solder balls encapsulated inside. Additionally, some of the conductive particles are embedded in the solder balls to mechanically joint and electrically connect to the ball pads.

The POP semiconductor device according to the present invention has the following advantages and effects:
1. Through the specific disposition of the ACA layer with a central opening between the top package and the bottom package, the ACA layer adheres the peripheries of the first upper surface of the bottom substrate to the peripheries of the second lower surface of the top substrate and encapsulate the solder balls. In addition to the embedded conductive particles in the solder balls, the joints of the embedded solder balls can greatly be enhanced and the substrate warpage can greatly be reduced to resolve the conventional failure of electrical connection due to the breaking of soldering points between the top package and the bottom package.
2. Through the partial encapsulation of conductive particles by the solder balls which are further bonded to the ball pads as a technical mean, the joint strength between the solder balls and the ball pads can be reinforced.
3. Through the encapsulation of solder balls by the ACA layer as a technical mean, the solder balls as the chip interconnections can be encapsulated and protected to avoid environmental contamination.

### DESCRIPTION OF THE DRAWINGS

FIG. 1 is a cross-sectional view of a conventional POP semiconductor device before assembly.

FIG. 2 is a cross-sectional view of the conventional POP semiconductor device after assembly showing warpage of its bottom substrate.

FIG. 3 is a cross-sectional view of a POP semiconductor device before assembly according to the first embodiment of the present invention.

FIG. 4 is a cross-sectional view of the POP semiconductor device after assembly according to the first embodiment of the present invention.

FIG. 5 is a partially enlarged cross-sectional view of FIG. 4.

FIG. 6 is a partially enlarged cross-sectional view of a POP semiconductor device according to a various embodiment of the present invention.

FIG. 7 is a cross-sectional view of a POP semiconductor device before assembly according to the second embodiment of the present invention.

FIG. 8 is a cross-sectional view of the POP semiconductor device after assembly according to the second embodiment of the present invention.

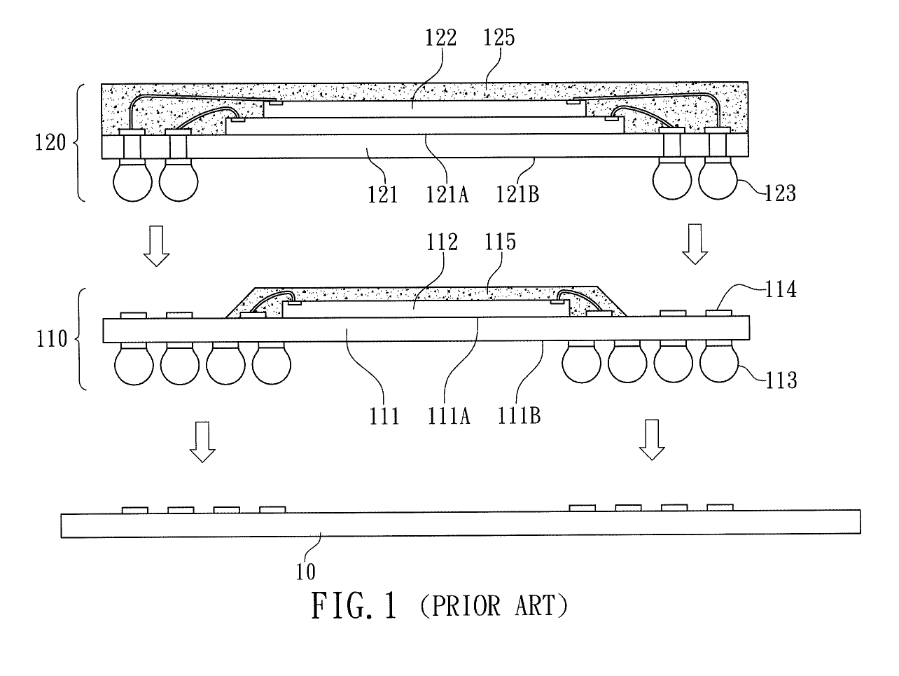

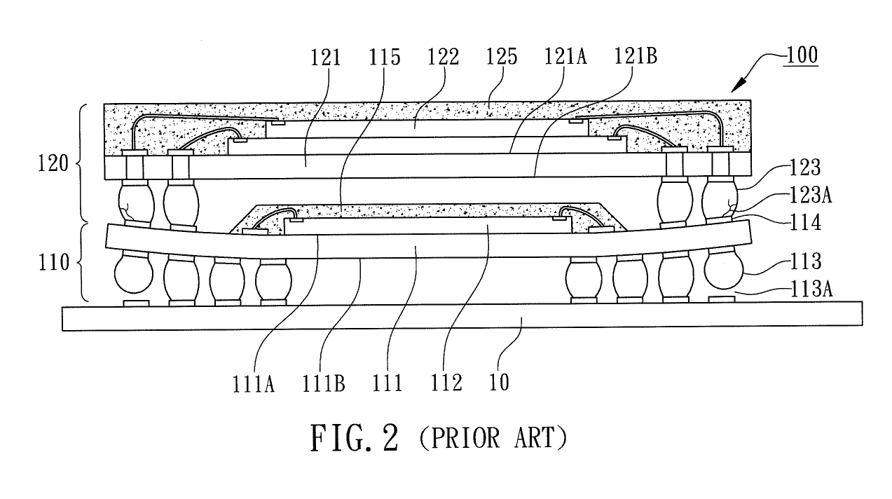

### DETAILED DESCRIPTION OF THE INVENTION

With reference to the attached drawings, the present invention is described by means of the embodiment(s) below where the attached drawings are simplified for illustration purposes only to illustrate the structures or methods of the present invention by describing the relationships between the components and assembly in the present invention. Therefore, the components shown in the figures are not expressed with the actual numbers, actual shapes, actual dimensions, nor with the actual ratio. Some of the dimensions or dimension ratios have been enlarged or simplified to provide a better illustration. The actual numbers, actual shapes, or actual dimension ratios can be selectively designed and disposed and the detail component layouts may be more complicated.

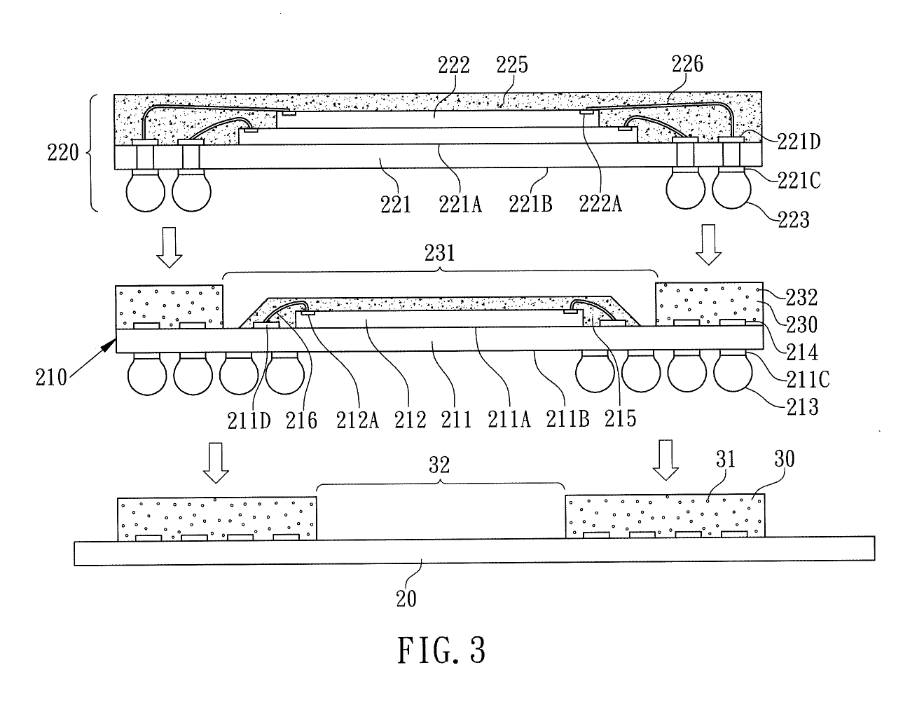

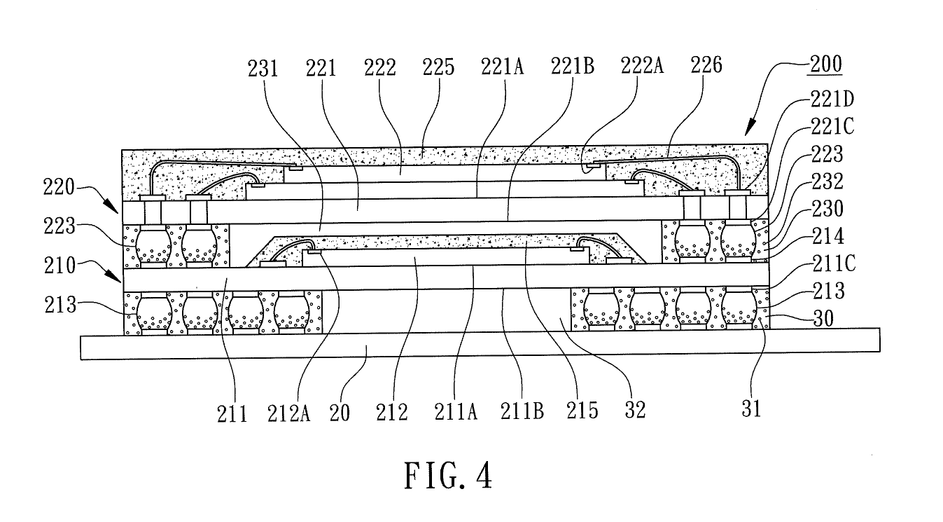

According to the first embodiment of the present invention, a POP semiconductor device is revealed in FIG. 3 for a cross-sectional view before assembly and in FIG. 4 for a cross-sectional view after assembly. The POP semiconductor device 200 primarily comprises a bottom package 210, a top package 220, and an anisotropic conductive adhesive (ACA) layer 230.

The bottom package 210 includes a first substrate 211, at least a first chip 212 disposed on the first substrate 211, and a plurality of external terminals 213. The first substrate 211 has a first upper surface 211A and a first lower surface 211B where a plurality of ball pads 214 are disposed at the peripheries of the first upper surface 211A. The external terminals 213 are disposed on the first lower surface 211B of the first substrate 211. The external terminals 213 may include solder balls, solder paste, contact pads, or contact pins. In the present embodiment, the external terminals 213 include a plurality of solder balls disposed on a plurality of outer pads 211C on the first lower surface 211B to make the bottom package 210 as a BGA package where the external terminals 213 can be SMT to a printed circuit board 20.

The top package 220 is mounted on the bottom package 210. The top package 220 includes a second substrate 221, one or more second chips 222 disposed on the second substrate 221 and a plurality of solder balls 223. The second substrate 221 has a second upper surface 221A and a second lower surface 221B. The solder balls 223 are disposed at the peripheries of the second lower surface 221B of the second substrate 221. The solder balls 223 can be made of tin-lead solder or lead-free solder such as Sn 96.5%-Ag 3%-Cu 0.5%. When the solder balls 223 experience the reflowing temperature above 217° C. with a maximum temperature of 245° C., the wetting properties of soldering are able to exhibit where the solder balls 223 are disposed on a plurality of second external connecting pads 221C on the second lower surface 221B which can be formed by ball placement, by printing, by plating, or by solder paste dipping and become solder balls after reflowing processes. After the formation of the ACA layer 230, the solder balls 223 will be soldered to the ball pads 214 of the first substrate 211 by another reflowing process to make electrical connection as shown in FIG. 4. Therefore, the top package 220 is SMT bonded to the bottom package 210 by the solder balls 223 penetrating through the ACA layer 230.

To be more specific, the bottom package 210 further includes a first encapsulant 215 formed on the first upper surface 211A of the first substrate 211 to encapsulate the first chip 212. The top package 220 further includes a second encapsulant 225 formed on the second upper surface 221A of the second substrate 221 to encapsulate the second chips 222.

To be described in more detail, the substrates 211 and 221 are multi-layer printed circuit boards made of FR-4, FR-5, BT resin mixed with reinforced glass fibers or flexible circuit boards made of PI (polyimide). The first chip 212 and the second chips 222 are disposed on the upper surfaces 211A and 221A of the substrates 211 and 221 respectively by double-sided tapes, liquid epoxy, or B-stage paste. A plurality of first bonding pads 212A of the first chip 212 are electrically connected to the first bonding fingers 211D of the first substrate 211 by a plurality of first bonding wires 216. Then, a first encapsulant 215 is formed by molding to encapsulate the first chip 212 and the first bonding wires 216 to prevent the moisture diffusion to complete the bottom package 210. Similarly, the second bonding pads 222A of the second chips 222 are electrically connected to the second bonding fingers 221D of the second substrate 221 by a plurality of second bonding wires 226. Then, a second encapsulant 225 is formed by molding to encapsulate the second chips 222 and the second bonding wires 226 to complete the top package 220. To be described in more detail, the first bonding pads 212A and the second bonding pads 222A can be disposed at the peripheries of the active surfaces of the first chip 212 and the second chips 222 arranged in a single row or in multiple rows to be external terminals for IC. Normally, the first bonding pads 212A and the second bonding pads 222A are made of Al or Cu. For further description, the first chip 212 can be a controller and the second chips 222 can be memory components, they are assembled in individual packages to achieve the purpose of an integrated system-in-package (SIP).

In the present embodiment, the second chips 222 in the top package 220 are plural and stacked together where a plurality of second bonding fingers 221D are disposed at the peripheries of the second upper surface 221A of the second substrate 221 where there is no ball pads disposed on the second upper surface 221A of the second substrate 221 to provide more space for the dispositions of more second chips 222 and more second bonding fingers 221D to electrically connect to the more second chips 222. Or, a plurality of ball pads are disposed at the peripheries of the second upper surface 221A of the second substrate 221 to stack more of the top packages. Moreover, the dimensions of the bottom package 210 can be the same as the top package 220 to assembly POP semiconductor devices 200 using the same SMT equipment.

As shown in FIG. 3 and FIG. 4, the ACA layer 230 has a central opening 231 and is interposed between the bottom package 210 and the top package 220. The size of the central opening 231 and the thickness of the ACA layer 230 are selected such that the ACA layer 230 adheres the peripheries of the first upper surface 211A of the first substrate 211 to the peripheries of the second lower surface 221B of the second substrate 221 and the solder balls 223 are encapsulated inside the ACA layer 230. By this specific interposition of the ACA layer 230, the bonding strength between the first substrate 211 and the second substrate 221 and the encapsulation and protection of the solder balls 223 are increased. Therein, the size of the central opening 231 should be larger than the disposed area of the first chip 212 such a manner that the ball pads 214 are not exposed from the ACA layer 230. When the first chip 212 is encapsulated by a first encapsulant 215, the size of the central opening 231 should also be larger than the formed area of the first encapsulant 215. In this embodiment, the size of the central opening 231 is approximately the same as or less than half of the area of the first upper surface 211A of the first substrate 211. Preferably, the thickness of the ACA layer 230 is slightly greater than the diameter of the solder balls 223 before reflowing process to provide enough height to adhere the peripheries of the first upper surface 211A of the first substrate 211 to the peripheries of the second lower surface 221B of the second substrate 221. Therefore, during thermal cycling tests or actual operation, the ACA layer 230 with a central opening 231 can greatly enhance the joints of embedded solder balls 223 and to effectively reduce substrate warpage of the bottom package 210 to resolve failure of electrical connection due to the breaking of soldering points between the top package 220 and the bottom package 210. Comparing to the conventional POP semiconductor devices without the implementation of ACA layers, since conventional spacing between solder balls between two stacked packages are empty without any encapsulant where encapsulant can not be easily filled into the gap between the bottom package and the top package which is too small for encapsulation. After repeating thermal cycling, conventional substrate of bottom package is easily warped and conventional exposed solder balls are easily oxidized, cracked, or fatigue leading to the breaking of soldering joints during product lifetime. Even if any underfill material is formed between the stacked packages after reflowing the solder balls, the substrate of bottom package had already been deformed during reflowing to break the jointing of solder balls at specific locations such as solder balls at the corners of the top package to excessive thermal stresses.

To be more specific, the ACA layer 230 can be anisotropic conductive paste (ACP) or anisotropic conductive film (ACF) where ACA layer 230 is made by mixing a plurality of conductive particles 232 with adhesive resin. Normally the conductive particles 232 have similar diameters and are evenly and appropriately distributed in adhesive resin to avoid direct contact between conductive particles 230 where the diameter of the conductive particles 232 is much smaller than the one of the solder balls 223 at least below one-fifth the diameter of the solder balls 223 so that the conductive particles 232 can easily be encapsulated by the solder balls 223. Furthermore, the melting points of the conductive particles 232 should be greater than the reflowing temperature of the solder balls 223 where the conductive particles 232 are silver powder or high-temperature ceramic particles coated with gold.

During the stacking and reflowing the bottom package 210 with the top package 220, the ACA layer 230 encapsulates all of the solder balls 223 to avoid environmental contamination. Moreover, during the reflowing processes, the conductive particles 232 enhance the joints of the solder balls 223 to the ball pads 214 where some of the conductive particles 232 are embedded in the solder balls 223 which will make the volume of the solder balls 223 become larger and joint to the ball pads 214 to increase the joint strength between the solder balls 223 and the ball pads 214 to achieve electrical connection between the bottom package 210 and the top package 220. Preferably, the solder balls 223 encapsulating some of the conductive particles 232 are reflowed to become ellipsoid to avoid bridging between adjacent solder balls 223 leading to electrical short.

The POP semiconductor device 200 of the present invention is most suitable for stacking packages with different dimensions of encapsulants where the first encapsulant 215 partially covers the first upper surface 211A of the first substrate 211. The size of the central opening 231 is larger than the formed area of the first encapsulant 215 such a manner that all of the ball pads 214 are completely located in the adhesive area of the ACA layer 230 on the first upper surface 211A. That is, the first encapsulant 215 is smaller than the central opening 231 of the ACA layer 230 and partially encapsulate the first upper surface 211A of the first substrate 211 to expose the peripheries of the first upper surface 211A of the first substrate 211. The second encapsulant 225 completely covers the second upper surface 221A of the second substrate 221. In processes, the ACA layer 230 having the central opening 231 is disposed on the first upper surface 211A of the first substrate 211 where the first encapsulant 215 is accommodated in the central opening 231. The central opening 231 is designed to avoid the obvious flowing shift of the conductive particles 232 when the ACA layer 230 is pressed by the top package 220. Through the disposition of the ACA layer 230 and the encapsulation of conductive particles 232 by the solder balls 230, substrate warpage of the bottom package 210 having smaller encapsulant volume can be suppressed without affecting the electrical connection between the bottom package 210 and the top package 220.

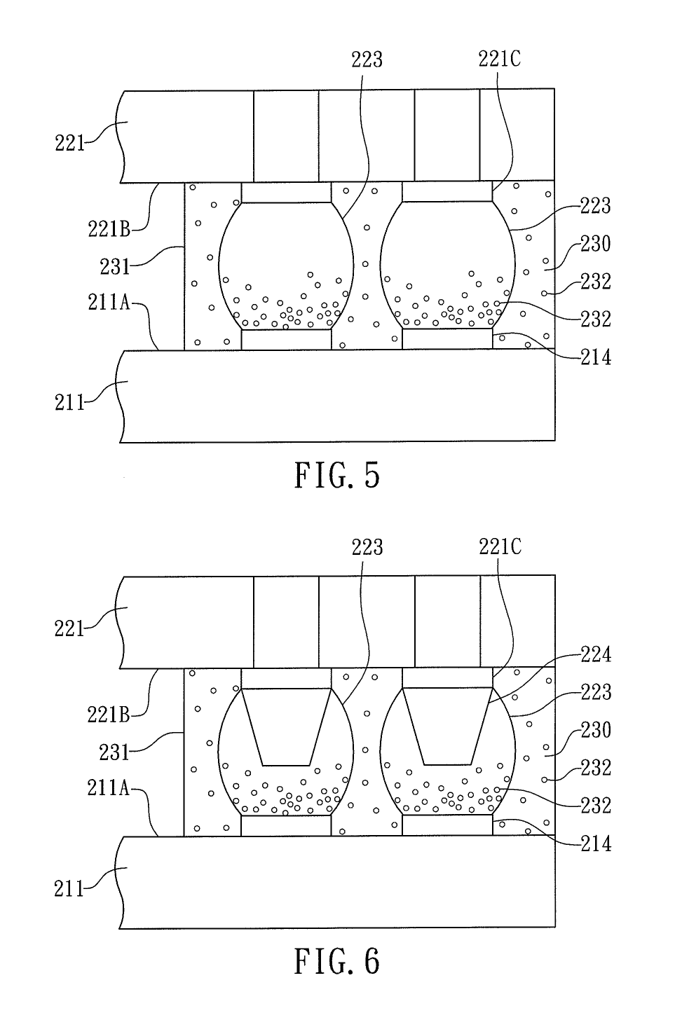

In the present embodiment, as shown in FIG. 4 and FIG. 5 for partially enlarged cross-sectional views, the ACA layer 230 can be a single-layer structure. Some of the conductive particles 232 are encapsulated by the solder balls 223 so that the ratio of the conductive particles 232 remained in the ACA layer 230 becomes fewer to further reduce the risk of bridging leading to electrical short between the solder balls 223.

Therefore, since the temperature of the POP semiconductor device 200 rises during thermal cycling tests or actual operation, the warpage of the bottom substrate 211 and the top substrate 221 can be similar due to the implementation of the ACA layer 230 to adhere the bottom substrate 211 to the top substrate 221 to enhance the joints of the encapsulated solder balls and to reduce the substrate warpage of the bottom package 210 to resolve the conventional failure of electrical connection due to the breaking of soldering points between the top package 220 and the bottom package 210. Preferably, the ACA layer 230 has higher Young's modulus, i.e., the strain of the ACA layer under the same stress is smaller than the strains of the first substrate 211 and the second substrate 221 to achieve the reinforcing function of an interposer to integrally keep the POP semiconductor device 200 intact with good package reliability.

In a various embodiment, as shown in FIG. 6 for a partially enlarged cross-sectional view, each solder ball 223 consists of a pillar core 224 and solder materials encapsulating the pillar core 224. To be described in more detail, the pillar core 224 can be non-reflow bump such as Au bumps, Cu bumps, Al bumps, or polymer conductive bumps where the shape of the pillar core 224 may be square, cylinder, pillar, cone, hemisphere or sphere. Preferably, the pillar core 224 can be a metal pillar such as a copper pillar having a high-temperature melting point without any deformation during reflowing processes to keep a minimum constant gap between the bottom package 210 and the top package 220 so that the solder balls 223 are not over-collapsed during reflowing processes and to constrain the conductive particles 232 at the bottom half of the solder balls 223.

As shown in FIG. 3, preferably, in order to further avoid the breaking of the soldering joints or poor soldering joints of the external terminals 213 due to the warpage of the first substrate 211, another ACA layer 30 can be disposed on the printed circuit board 20 so that the first substrate 211 can be firmly fixed by a sandwich structure where the material of the ACA layer 30 can be the same as the ACA layer 230 described afore. The ACA layer 30 has a plurality of conductive particles 31 and a central opening 32 to encapsulate only the portion where external terminals 213 are disposed where the central opening 32 of the ACA layer 30 is formed on the remaining portion without any external terminals 213 to save the cost of ACA layer 30. In this embodiment, the central opening 32 of the ACA layer 30 on the PCB 20 is smaller than the central opening 231 of the ACA layer 230 between the packages 210 and 220.

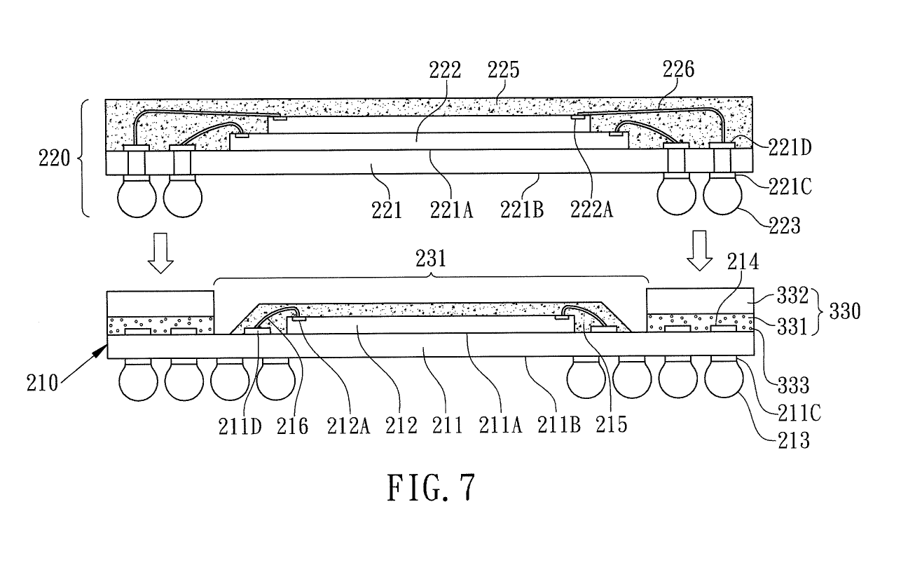

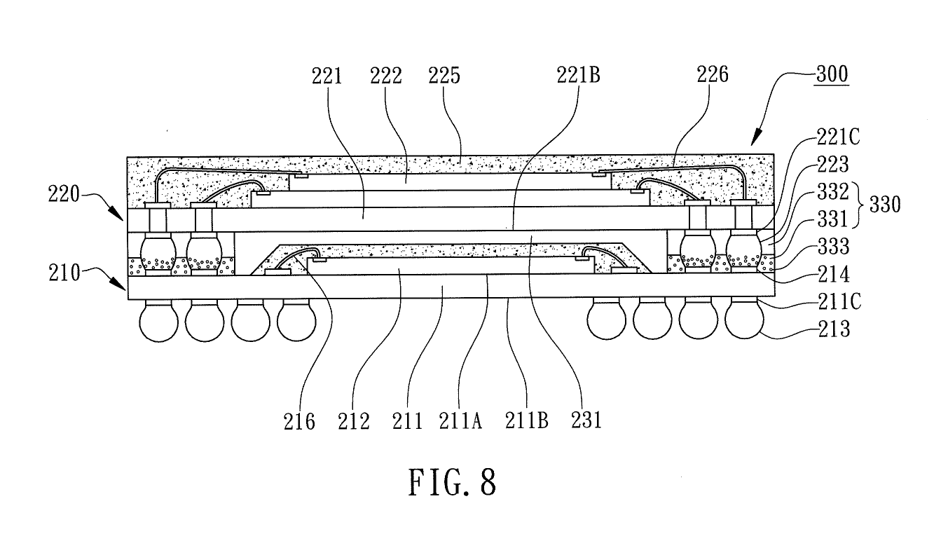

In the second embodiment of the present invention, another POP semiconductor device is revealed and illustrating in FIG. 7 for a cross-sectional view before assembly and FIG. 8 for a cross-sectional view after assembly. The POP semiconductor device 300 primarily comprises a bottom package 210, a top package 220, and an ACA layer 330 where the major components with the same functions as described in the first embodiment will be described with the same numbers without any further description herein.

The ACA layer 330 having a central opening 231 is interposed between the bottom package 210 and the top package 220 to adhere the peripheries of the first upper surface 211A of the first substrate 211 to the peripheries of the second lower surface 221B of the second substrate 221. In the present embodiment, the ACA layer 330 can be a multi-layer structure having a bottom layer 331 and a top layer 332 where the bottom layer 331 is attached to the first substrate 211 and contains more conductive particles than the ones in the top layer 332. Moreover, the thickness of the bottom layer 331 is smaller than the one of the top layer 332 so that the conductive particles 330 can be concentrated at the bottom layer 331 of the ACA layer 330 to increase the number of conductive particles 333 encapsulated by the solder balls 223 and to reduce the risk of electrical short between adjacent solder balls 223.

In a more specific embodiment, the top layer 332 can be a dielectric layer without any conductive particles, and the top layer 332 is thicker than the bottom layer 331. Under high-temperature reflowing processes, the solder balls 223 can encapsulate more conductive particles 333 at their bottom halves to enhance the jointing to the ball pads 214. The bonding between the solder balls 223 and the ball pads 214 ensures the electrical connections between the bottom package 210 and the top package 220. Therefore, the thickness of the ACA layer 330 can be slightly greater than the diameter of the solder balls 223 before reflowing process without affecting the electrical interconnection to assure substrate adhesion between the bottom package 210 and the top package 220.

Therefore, through the disposition of the ACA layer 330 having the central opening 231 interposed between the bottom package 210 and the top package 220 to adhere the peripheries of the first upper surface 211A of the bottom substrate 211 to the peripheries of the second lower surface 221B of the top substrate 221 as a technical mean, the substrate warpage can greatly be reduced and the joints of the encapsulated solder balls 223 can greatly be enhanced to resolve the conventional failure of electrical connection due to the breaking of soldering points between the two stacked packages.

The above description of embodiments of this invention is intended to be illustrative but not limited. Other embodiments of this invention will be obvious to those skilled in the art in view of the above disclosure which still will be covered by and within the scope of the present invention even with any modifications, equivalent variations, and adaptations.

What is claimed is:

1. A POP semiconductor device comprising:
a bottom package including a first substrate, at least a first chip disposed on a first upper surface of the first substrate, a plurality of external terminals disposed on a first lower surface of the first substrate, wherein a plurality of ball pads are disposed at a plurality of peripheries of the first upper surface of the first substrate;
a top package mounted on the bottom package, the top package including a second substrate, one or more second chips disposed on a second upper surface of the second substrate, and a plurality of solder balls, wherein the solder balls are disposed at a plurality of peripheries of a second lower surface of the second substrate; and
an anisotropic conductive adhesive layer interposed between the bottom package and the top package, the anisotropic conductive adhesive layer having a central opening, wherein the anisotropic conductive adhesive layer contains a plurality of conductive particles;
wherein the size of the central opening and the thickness of the anisotropic conductive adhesive layer are selected such that the anisotropic conductive adhesive layer adheres the peripheries of the first upper surface of the first substrate to the peripheries of the second lower surface of the second substrate and the solder balls are encapsulated inside, wherein some of the conductive particles are embedded in the solder balls to mechanically joint and electrically connect to the ball pads.

2. The POP semiconductor device as claimed in claim 1, wherein more than half of the embedded conductive particles are concentrated at a bottom half of the solder balls facing to the ball pads.

3. The POP semiconductor device as claimed in claim 2, wherein the solder balls are reflowed to become ellipsoid.

4. The POP semiconductor device as claimed in claim 1, wherein the thickness of the anisotropic conductive adhesive layer is slightly greater than the diameter of the solder balls.

5. The POP semiconductor device as claimed in claim 1, wherein each solder ball consists of a pillar core and solder materials encapsulating the pillar core.

6. The POP semiconductor device as claimed in claim 1, wherein the bottom package further includes a first encapsulant formed on the first upper surface of the first substrate to encapsulate the first chip, wherein the top package further includes a second encapsulant formed on the second upper surface of the second substrate to encapsulate the second chips.

7. The POP semiconductor device as claimed in claim 6, wherein the first encapsulant partially covers the first upper surface of the first substrate, and the size of the central opening is larger than the formed area of the first encapsulant such a manner that all of the ball pads are completely located in the adhesive area of the anisotropic conductive adhesive layer.

8. The POP semiconductor device as claimed in claim 7, wherein the second encapsulant completely covers the second upper surface of the second substrate.

9. The POP semiconductor device as claimed in claim 8, wherein the first chip is a controller and the second chips are memory components.

10. The POP semiconductor device as claimed in claim 1, wherein the anisotropic conductive adhesive layer is a single-layer structure.

11. The POP semiconductor device as claimed in claim 1, wherein the anisotropic conductive adhesive layer is a multi-layer structure having a bottom layer and a top layer, wherein the bottom layer is attached to the first upper surface of the first substrate and contains more conductive particles than the ones in the top layer.

12. The POP semiconductor device as claimed in claim 11, wherein the top layer of the anisotropic conductive adhesive layer is a dielectric layer without any conductive particles, and the top layer is thicker than the bottom layer.

13. The POP semiconductor device as claimed in claim 1, further comprising:
a printed circuit board wherein the bottom package is mounted on the printed circuit board by the external terminals; and
a second anisotropic conductive adhesive layer disposed on the printed circuit board, the second anisotropic conductive adhesive layer adheres the printed circuit board to the first lower surface of the first substrate and the external terminals are encapsulated inside.

14. The POP semiconductor device as claimed in claim 13, wherein the second anisotropic conductive adhesive layer has a second opening smaller than the central opening of the anisotropic conductive adhesive layer.
